(19) United States
(12) Patent Application Publication
(10) Pub. No.: US 2009/0081879 A1
(43) Pub. Date: Mar. 26, 2009

(54) METHOD FOR MANUFACTURING SEMICONDUCTOR DEVICE

(75) Inventor: Mitsunari SUKEKAWA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/212,236

(22) Filed: Sep. 17, 2008

(30) Foreign Application Priority Data
Sep. 20, 2007 (JP) 2007-243987

(51) Int. Cl. H01L 21/302

(52) U.S. Cl. 438/735; 257/E21.311

(57) ABSTRACT

There is provided a method for manufacturing a semiconductor device including processing a substrate to be processed by using an amorphous carbon hard mask that includes processing an amorphous carbon film formed on the substrate to be processed to provide a hard mask, and forming a protective film comprising a silicon oxide film on a sidewall of the amorphous carbon film exposed during or after processing the amorphous carbon film; and the protective film preferably formed by sputtering an intermediate mask comprising at least a silicon oxide on the amorphous carbon film.

### BACKGROUND OF THE INVENTION

1. Field of the Invention

The present invention relates to a method for manufacturing a semiconductor device, and more specifically, to a method for manufacturing a semiconductor device that uses an amorphous carbon film as a hard mask.

2. Description of Related Art

With the progress of the semiconductor micro-fabrication techniques in recent years, an ArF resist that is patterned by short-wavelength light has been increasingly used. The ArF resist has low dry-etching resistance and is formed into a thin film due to shallow depth of focus. Therefore, a hard mask that has high dry-etching resistance and thick film thickness is required, and techniques that use amorphous carbon or the like as the material for the hard mask have been disclosed (for example, Japanese Patent Application Laid-Open No. 2002-194547).

FIGS. 5A to 5D are process sectional views that show a method for manufacturing a conventional semiconductor device using amorphous carbon as a hard mask.

As shown in FIG. 5A, silicon oxide film 4, amorphous carbon film 3, intermediate mask layer 2 composed of laminated film of a silicon oxynitride film and a silicon oxide film are formed on lower wiring 5, and contact pattern 1 composed of a photoresist material is patterned using lithography technique. Since the etching selectivity of the photoresist mainly composed of organic carbon compounds to amorphous carbon is difficult to obtain, intermediate mask layer 2 is provided so that the pattern is once transferred to the intermediate mask layer and then transferred to the amorphous carbon film. The intermediate mask layer is also used as an antireflection for the photoresist. Next, as shown in FIG. 5B, intermediate mask layer 2 is processed to intermediate mask 2a using a dry etching process. At this time, fluorine-containing gas such as CF₄ is used as the etching gas.

Next, as shown in FIG. 5C, amorphous carbon film 3 is processed using intermediate mask 2a as a hard mask. At this time, oxygen is used as the etching gas. Since a gas system that contains no fluorine is used for etching, amorphous carbon film 3 is selectively etched, and contact pattern 1 formed of a thin resist film can be transferred to thick amorphous carbon film 3 as amorphous carbon hard mask 3a.

Next, as shown in FIG. 5D, silicon oxide film 4 is etched using fluorine-containing gas such as C₄F₈ gas using amorphous carbon hard mask 3a as a mask to process contact hole 7.

Thereafter, the remaining amorphous carbon hard mask is removed using oxygen or ozone plasma ashing or the like.

When the amorphous carbon film is processed, since oxygen radicals used as the etchant have a strong reactivity with amorphous carbon film 3, amorphous carbon film 3 can be processed at a high etching rate; however, amorphous carbon film 3 is etched in the lateral direction. Therefore, a problem wherein contact opening 6 formed in amorphous carbon hard mask 3a has a bowing shape as shown in FIG. 5C is caused. In addition, if amorphous carbon hard mask 3a has such a bowing shape, contact hole 7 tends to have a bowing shape as shown in FIG. 5D, and a problem wherein the defective contact is formed is also caused.

When the amorphous carbon hard mask is processed to have a fine linear pattern, a problem wherein the slimming of the pattern occurs and a desired pattern cannot be obtained is caused.

In the fine linear pattern, there is concern that the pattern tilting of the amorphous carbon hard mask when the substrate to be processed is etched. Furthermore, in any of fine linear patterns and opening patterns, the problem of pattern deformation may also be caused when the substrate to be processed is etched.

Japanese Patent Application Laid-Open No. 2005-45053 discloses that if an Si-containing amorphous carbon film is used as a hard mask when the amorphous carbon film is etched using oxygen, oxygen reacts with silicon containing the amorphous carbon hard mask to form an oxide film on the surface of the hard mask, and the side etching of the hard mask can be suppressed. However, depending on conditions of the diffusion of Si, since the thickness of the oxide film formed on the sidewall differs in parts, Si in the portion to be removed is also oxidized, and the deposition of the oxide on the exposed surface of the substrate to be processed is a concern, there is room for further improvement.

Therefore, when the amorphous carbon film is processed to have the shape of a hard mask, the provision of a method for forming an amorphous carbon hard mask that causes no bowing or pattern slimming is desired. In addition, a method to prevent toppling or deformation of the amorphous carbon hard mask is desired.

### SUMMARY

The present invention seeks to solve one or more of the above problems, or to improve upon those problems at least in part.

In one embodiment, there is provided a method for manufacturing a semiconductor device that includes processing a substrate to be processed by using an amorphous carbon hard mask, including:

processing a silicon-free amorphous carbon film formed on the substrate to be processed to provide a hard mask, and

forming a protective film on a sidewall of the amorphous carbon film exposed during or after processing the amorphous carbon film.

In another embodiment, there is provided a method for manufacturing a semiconductor device that includes processing a substrate to be processed by using an amorphous carbon hard mask, including:

processing an amorphous carbon film formed on the substrate to be processed to provide a hard mask, and

forming a protective film on a sidewall of the amorphous carbon film exposed during or after processing the amorphous carbon film under the atmosphere containing no oxygen.

According to the present embodiments, when the amorphous carbon film is processed to have a hard mask shape, the side etching of the amorphous carbon film can be prevented and a vertical shape that has a high anisotropy can be obtained, by processing the amorphous carbon film, forming the protective film on the sidewall of the amorphous carbon film, in the middle of the processing, and further processing the amorphous carbon film.

### BRIEF DESCRIPTION OF THE DRAWINGS

The above features and advantages of the present invention will be more apparent from the following description of certain embodiments taken in conjunction with the accompanying drawings, in which:

FIGS. 1A to 1F are process sectional views that illustrate a method for manufacturing a semiconductor device according to an exemplary embodiment of the present invention;

FIGS. 2A to 2F are process sectional views that illustrate a method for manufacturing a semiconductor device according to another exemplary embodiment of the present invention;

FIGS. 3A and 3B are process sectional views that illustrate a modification of another exemplary embodiment of the present invention;

FIG. 4 is a schematic diagram that shows the configuration of a magnetized RIE dry etching apparatus used in the exemplary embodiments of the present invention; and

FIGS. 5A to 5D are process sectional views that illustrate a conventional method for manufacturing a semiconductor device.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### FIRST EXEMPLARY EXAMPLE

In the first exemplary example, there is provided a method for manufacturing a semiconductor device that includes:

(A) forming a silicon-free amorphous carbon film on a substrate to be processed, and forming an intermediate mask layer comprising at least a silicon dioxide film on the amorphous carbon film;

(B) processing the intermediate mask layer into an intermediate mask shape;

(C) etching a part of the amorphous carbon film using the processed intermediate mask layer as a mask to expose a sidewall of the amorphous carbon film;

(D) sputtering the intermediate mask layer to form a protective film comprising a silicon oxide on the sidewall of the amorphous carbon film;

(E) further etching the amorphous carbon film until the substrate to be processed is exposed by using the remaining intermediate mask layer and the protective film as a mask; and

(F) processing the substrate to be processed using the amorphous carbon film as a mask.

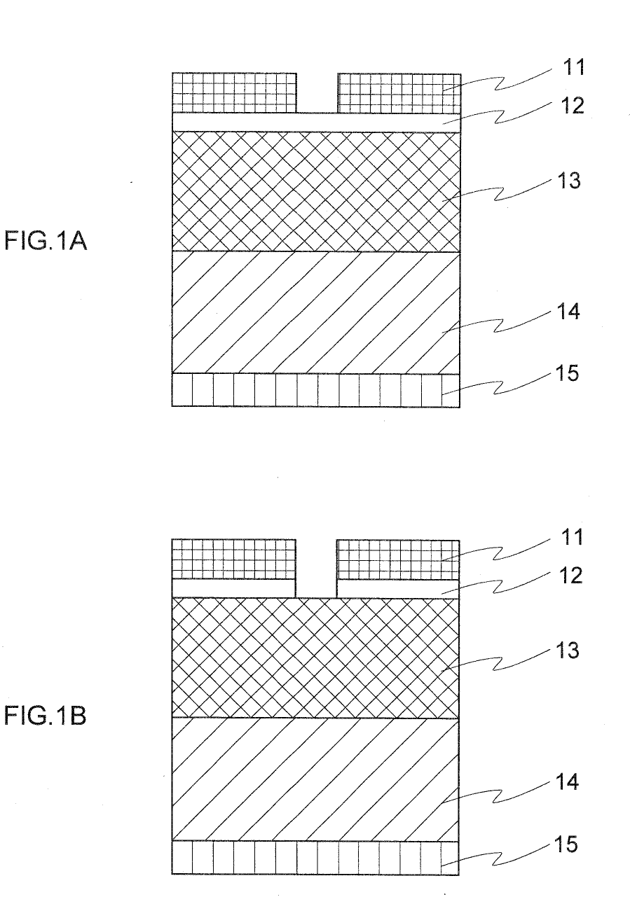

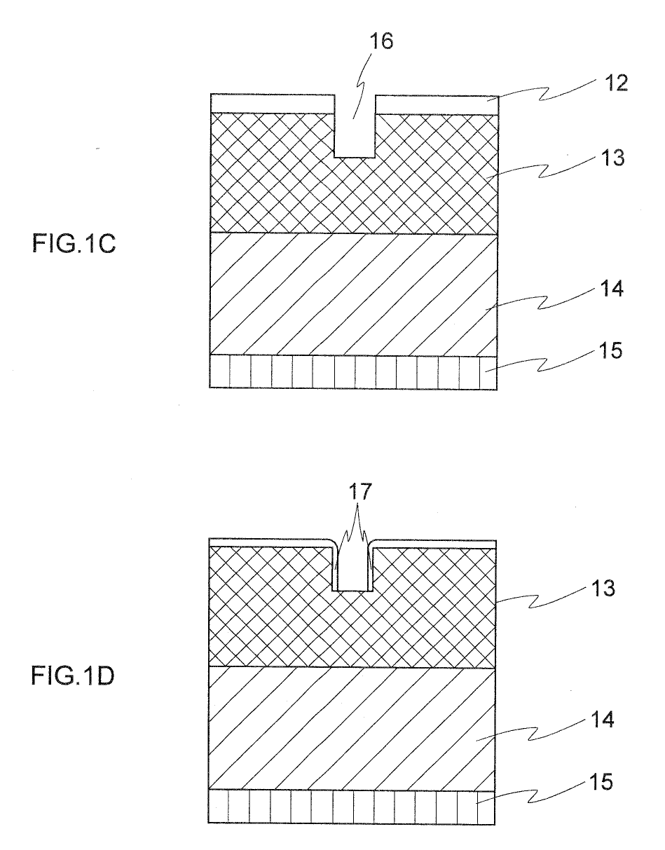

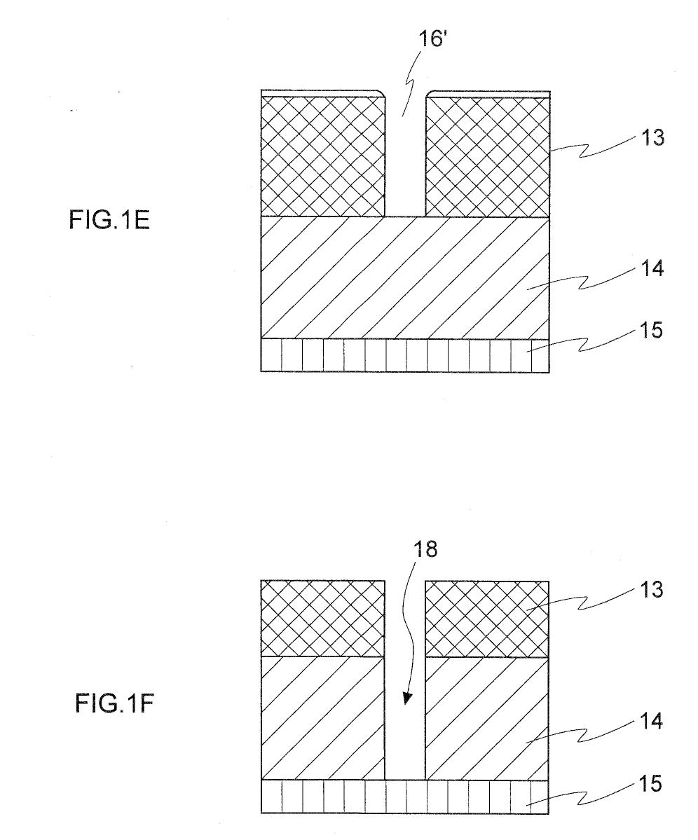

The above Steps (A) to (F) will be described referring to FIGS. 1A to 1F, which are process sectional views.

First in Step (A), as shown in FIG. 1A, silicon dioxide film 14, amorphous carbon film 13, and laminated film composed of a silicon oxynitride film and a silicon dioxide film to be intermediate mask layer 12 are formed on lower wiring 15; and contact hole pattern 11 composed of a photoresist material is patterned using lithography. Amorphous carbon film 13 is formed using a method wherein a hydrocarbon compound CₓH_{y}, such as propylene, and an inert gas, such as Ar and He, are supplied into a plasma chamber; the mixed gas is thermally decomposed by plasma; and the amorphous carbon film is deposited on a wafer in the chamber. At this time, the temperature of the wafer is, for example, 100° C. to 600° C., and the pressure in the chamber is about 133 Pa to about 2.67 kPa (about 1 Torr to about 20 Torr). Thus produced amorphous carbon film is substantially free from silicon. Intermediate mask layer 12 is a laminated film of a silicon oxynitride film and a silicon dioxide film formed by CVD method, and the thicknesses of the silicon oxynitride film and the silicon dioxide film are 10 to 30 nm and 30 to 100 nm, respectively.

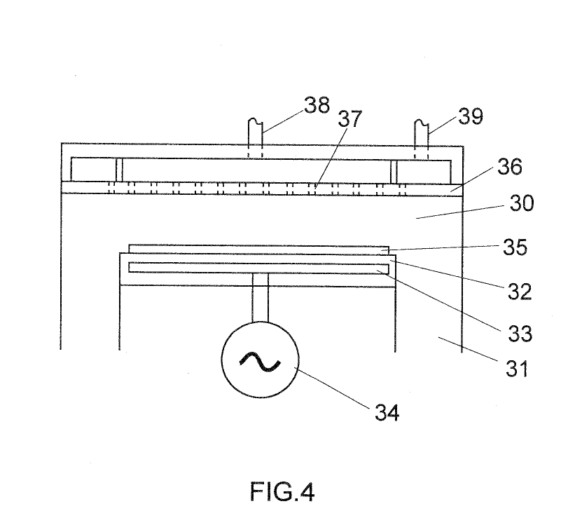

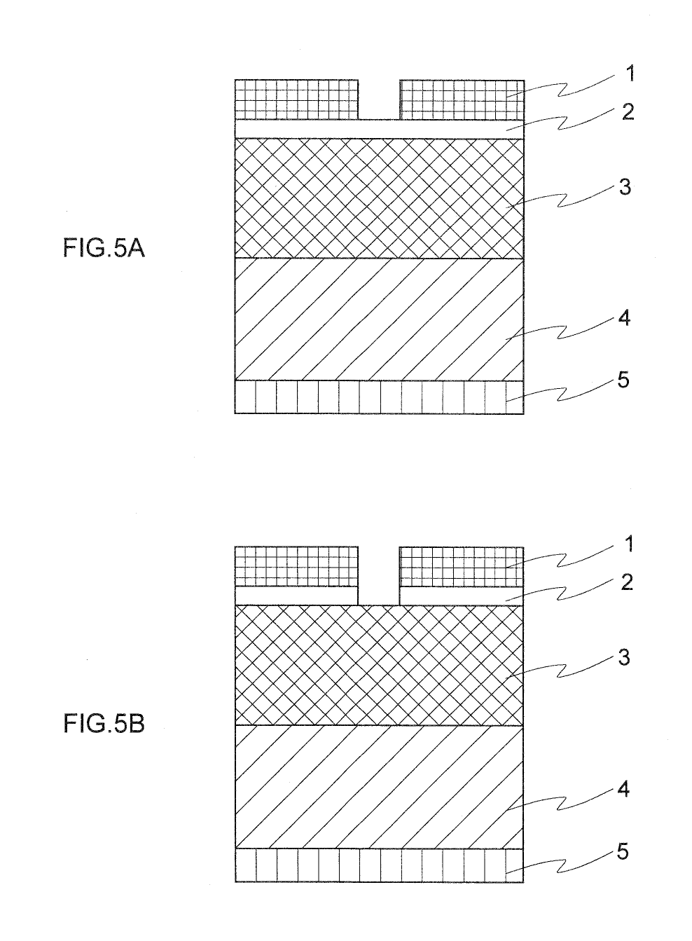

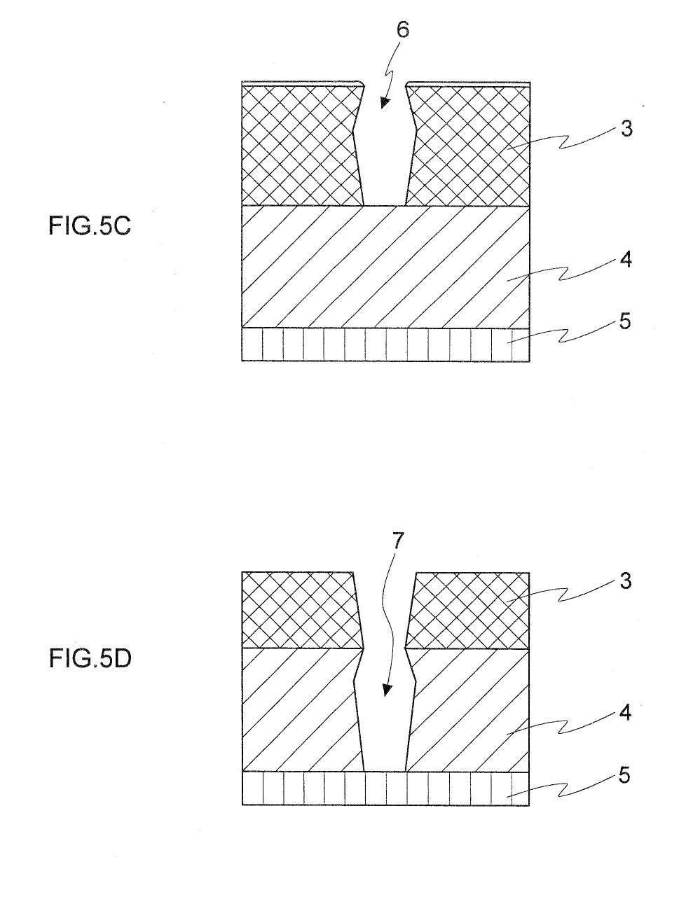

Next, in Step (B), as shown in FIG. 1B, intermediate mask layer 12 is processed by dry etching. Here, intermediate mask layer 12 is processed with a magnetized RIE dry etching apparatus of an RF frequency of 13.56 MHz shown in FIG. 4. In etching intermediate mask layer 12, CF₄ is used as the etching gas, the chamber pressure is controlled at 4.0 to 20.0 Pa (30 to 150 mTorr), the RF power is set between 300 and 2,000 W, and the stage temperature is 0 to 60° C. After etching, the shape shown in FIG. 1B is formed.

The apparatus shown in FIG. 4 is an apparatus for processing wafer 35 placed in plasma chamber 30, and wafer 35 is electrostatically fixed on electrostatic chuck stage 32. In electrostatic chuck stage 32, a lower electrode connected to RF power source 34 is disposed. In plasma chamber 30, upper electrode 36 is provided so as to face to the wafer, and upper electrode 36 is equipped with gas blowout holes 37. During the dry etching process, the atmospheric gases are once discharged from chamber 30 through exhaust port 31, an etchant gases are introduced through center gas line 38 and edge gas line 39, and the gases are evenly introduced from gas blowout holes 37.

Next, in Step (C), as shown in FIG. 1C, amorphous carbon film 13 is processed using processed intermediate mask 12a as a mask. In the same manner as described above, amorphous carbon film 13 is partially etched using the apparatus shown in FIG. 4 to form opening 16. At this time, oxygen and argon are used as the etchant gases, the chamber pressure is controlled at 1.33 to 6.67 Pa (10 to 50 mTorr), and the RF power is set between 200 and 1,000 W. The etching time is adjusted so that no resist material remains.

Next, in Step (D), as shown in FIG. 1D, intermediate mask 12a is sputtered by using a gas system that contains no oxygen to form protective film 12b of the oxide derived from intermediate mask 12a on the sidewall of opening 16 formed in amorphous carbon film 13. At this time, argon is used as a sputtering gas, the chamber pressure is controlled at 1.33 to 6.67 Pa (10 to 50 mTorr), and the RF power is set between 200 and 1,000 W.

Next, in Step (E), as shown in FIG. 1E, amorphous carbon film 13 is etched until underlying silicon dioxide film 14 is exposed to form amorphous carbon hard mask 13a that has opening 16′. At this time, oxygen and argon are used as the etchant gases, the chamber pressure is controlled at 1.33 to 6.67 Pa (10 to 50 mTorr), and the RF power is set between 200 and 1,000 W. Oxide protective film 12b on the bottom of opening 16 in amorphous carbon film 13 in Step (D) is too thin to interfere with etching.

Next, in Step (F), as shown in FIG. 1F, silicon dioxide film 14 is processed by dry etching using a fluorine-containing gas such as C₄F₈ gas through amorphous carbon hard mask 13a, and a bottom layer produced during the etching of silicon oxide film 14 is removed by using oxygen gas to form contact hole 17 in silicon dioxide film 14.

As etching gas in Step (B), fluorocarbon gas, such as CHF₃, CH₂F₂, CH₃F, C₄F₆, and C₅F₈ can be used.

By using a mixed gas of hydrogen and nitrogen as the etching gas for the amorphous carbon film in Step (C), the expansion of the aperture of opening 16 can be prevented compared with the case using oxygen. In this case, it is preferable that the chamber pressure is controlled at 6.67 to 26.7 Pa (50 to 200 mTorr), the RF power is set between 400 and 3,000 W, the stage temperature is 60° C., and the flow ratio of hydrogen and nitrogen gases is 2:1 to 4:1.

Also as the etching gas in Step (E), a mixed gas of hydrogen and nitrogen can be used in the same manner.

In the above description, although the process for forming the oxide protective film on the sidewall of the amorphous carbon film is conducted only once, if the amorphous carbon film is thick, the intermediate mask layer for forming the oxide film may be sputtered every time the amorphous carbon film is processed to have a predetermined depth.

According to the above first exemplary embodiment, by forming the protective film to be formed on the sidewall of the amorphous carbon film using sputtering of the intermediate mask layer for transferring the pattern to the amorphous carbon film, batch processing can be feasible, the process can be simplified, and at the same time, the processed shape that has no pattern dependence can be obtained.

In the sputtering of the intermediate mask layer, since substantially no protective film is formed on the bottom of the pattern, the amorphous carbon film can be processed without adding an oxide-film etching process, and time for processing can be shortened and the process margin can be expanded.

### SECOND EXEMPLARY EXAMPLE

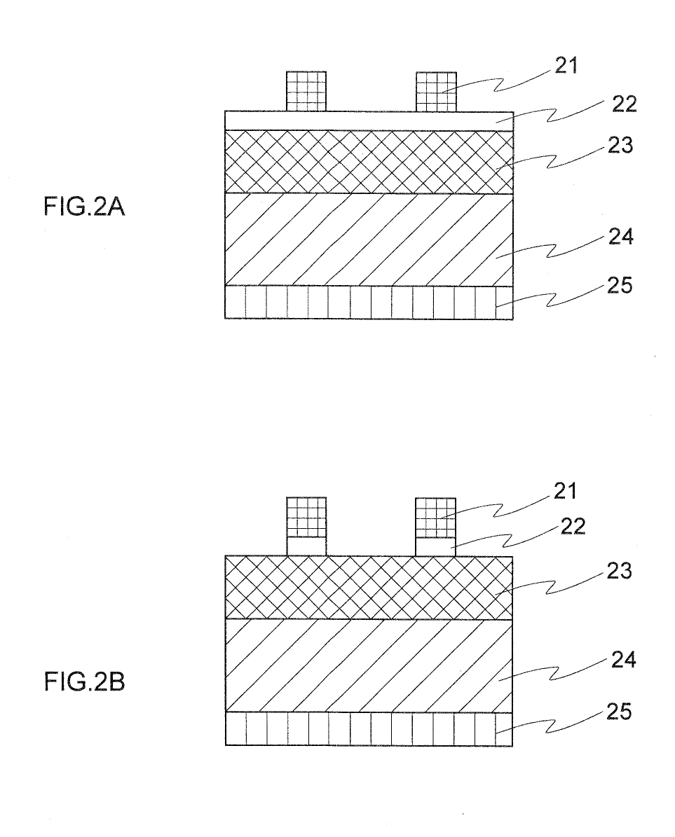

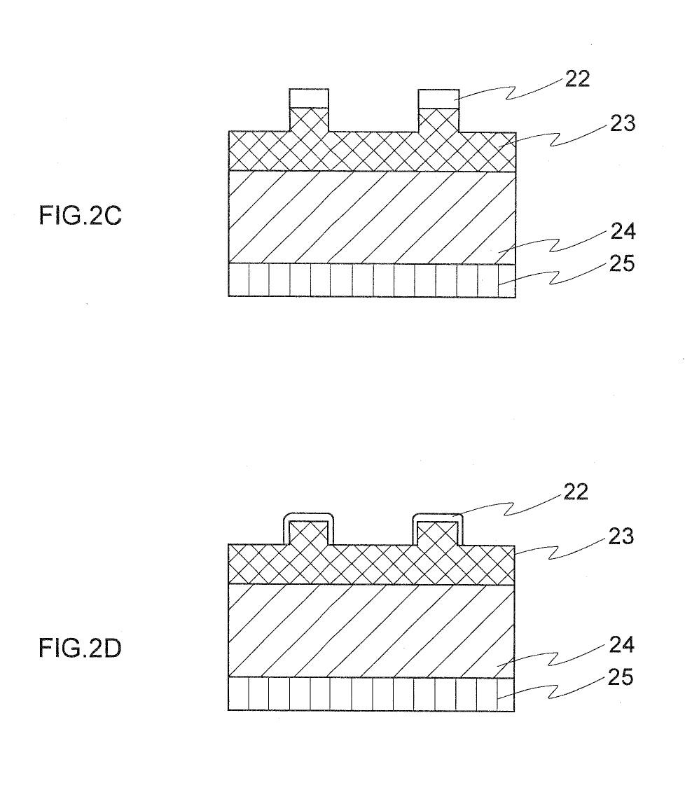

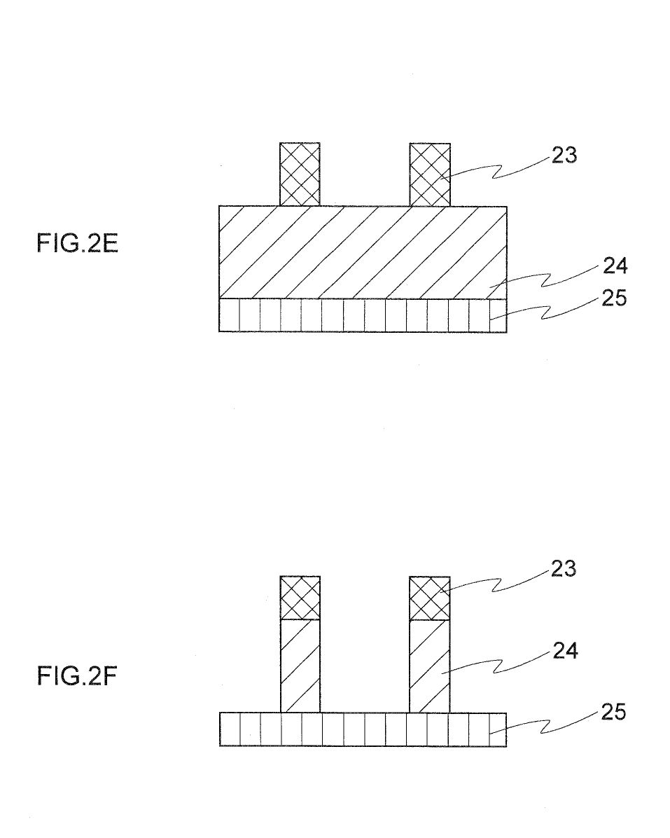

A manufacturing method for a second exemplary example will be described referring to FIGS. 2A to 2F.

First as shown in FIG. 2A, silicon nitride film 24, amorphous carbon film 23, and intermediate mask layer 22 are formed on wiring material 25 using CVD, and wiring resist pattern 21 is formed using lithography. Intermediate mask layer 22 is a laminated film of a silicon oxynitride film and a silicon oxide film formed by plasma CVD, and the thicknesses of the silicon oxynitride film and the silicon oxide film are 10 to 30 nm and 30 to 100 nm, respectively.

Next, using a magnetized RIE dry etching apparatus of an RF frequency of 13.56 MHz shown in FIG. 4, intermediate mask layer 22 and amorphous carbon film 23 are processed. CF₄ is used as the etching gas for intermediate mask layer 22, the chamber pressure is controlled at 4.0 to 20.0 Pa (30 to 150 mTorr), the RF power is set between 300 and 2,000 W, and the stage temperature is 0 to 60° C. After etching, intermediate mask 22a as shown in FIG. 2B is formed.

Next, as shown in FIG. 2C, amorphous carbon film 23 is partially etched. At this time, oxygen and argon are used as the etchant gases, the chamber pressure is controlled at 1.33 to 6.67 Pa (10 to 50 mTorr), and the RF power is set between 200 and 1,000 W.

Next, as shown in FIG. 2D, intermediate mask 22a is sputtered by using a gas system that contains no oxygen to form protective film 22b of the oxide derived from intermediate mask 22a on the sidewall of amorphous carbon film 23. Argon is used as the gas system, the chamber pressure is controlled at 1.33 to 6.67 Pa (10 to 50 mTorr), and the RF power is set between 200 and 1,000 W.

Next, as shown in FIG. 2E, amorphous carbon film 23 is etched until underlying silicon nitride film 24 is exposed to form amorphous carbon hard mask 23a. At this time, oxygen and argon are used as the etching gas, the chamber pressure is controlled at 1.33 to 6.67 Pa (10 to 50 mTorr), and the RF power is set between 200 and 1,000 W.

Next, as shown in FIG. 2F, silicon nitride film 24 is processed by dry etching using a fluorine-containing gas such as CF₄ gas, and a bottom layer produced during the etching of silicon nitride film 24 is removed by using oxygen gas to transfer the pattern to silicon nitride film 24.

Thereby, amorphous carbon film 23 can be prevented from slimming.

### THIRD EXEMPLARY EMBODIMENT

Even when the thickness of the amorphous carbon film is not excessively thick, and slimming does not cause major problems, the formation of a protective film by the sputtering of the intermediate mask layer can be used in order to improve the pattern accuracy.

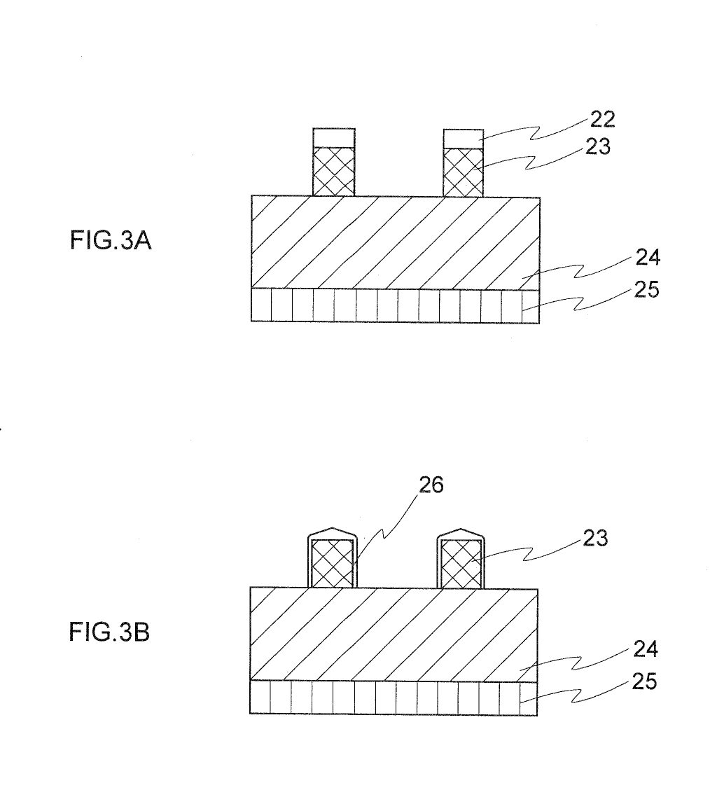

After processing to the state shown in FIG. 2B in the same manner as described above, amorphous carbon film 23 is etched as shown in FIG. 3A.

Next, as shown in FIG. 3B, intermediate mask 22a is sputtered by etching using a gas system that contains no oxygen to form protective film 22c of the oxide on the sidewall of amorphous carbon film 23. Thereafter, in the same manner as described above, silicon nitride film 24 is processed by dry etching using a fluorine-containing gas such as CF₄ gas, and a bottom layer produced during the etching of silicon nitride film 24 by is removed using oxygen gas so that the transferring the pattern to silicon nitride film 24 is completion.

By thus protecting the amorphous carbon hard mask pattern itself with the protective film, the pattern accuracy in the dry etching of the substrate to be processed is further improved. This exemplary example is also applicable to other than line patterns, for example, to opening (hole) patterns as shown in the first exemplary example.

As application examples of the present invention, the formation of an opening for forming a cylindrical capacitor and the formation of a fine contact hole in the manufacturing method of a DRAM semiconductor device used in a storage device are mentioned.

It is apparent that the present invention is not limited to the above embodiments, but may be modified and changed without departing from the scope and spirit of the invention.

What is claimed is:

1. A method for manufacturing a semiconductor device that includes processing a substrate to be processed by using an amorphous carbon hard mask, comprising:
processing a silicon-free amorphous carbon film formed on the substrate to be processed to provide a hard mask, and
forming a protective film on a sidewall of the amorphous carbon film exposed during or after processing the amorphous carbon film.

2. The method for manufacturing a semiconductor device according to claim 1, wherein processing a silicon-free amorphous carbon film is performed by using an intermediate mask layer formed on the amorphous carbon film as a mask and the protective film on a sidewall of the amorphous carbon film is formed by sputtering the remaining intermediate mask layer.

3. The method for manufacturing a semiconductor device according to claim 2, wherein the intermediate mask layer comprises at least silicon dioxide and the protective film comprises the silicon dioxide.

4. The method for manufacturing a semiconductor device according to claim 2, wherein sputtering the remaining intermediate mask layer is performed using a gas system containing no oxygen.

5. The method for manufacturing a semiconductor device according to claim 1, wherein processing a silicon-free amorphous carbon film to provide a hard mask comprises:
forming the amorphous carbon film on the substrate to be processed, and forming an intermediate mask layer on the amorphous carbon film;
processing the intermediate mask layer into a mask shape for a predetermined pattern;
etching a part of the amorphous carbon film using the processed intermediate mask layer as a mask to expose a sidewall of the amorphous carbon film;
sputtering the intermediate mask layer to form a protective film on the sidewall of the amorphous carbon film; and
further etching the amorphous carbon film using the remaining intermediate mask layer and the protective film on the sidewall of the amorphous carbon film as a mask.

6. The method for manufacturing a semiconductor device according to claim 5, wherein the intermediate mask layer comprises at least silicon dioxide and the protective film comprises the silicon dioxide.

7. The method for manufacturing a semiconductor device according to claim 5, wherein sputtering the intermediate mask layer is performed using a gas system containing no oxygen.

8. The method for manufacturing a semiconductor device according to claim 1, wherein after the amorphous carbon film has been processed until the substrate to be processed is exposed, the protective film is formed on the sidewall of the processed amorphous carbon film.

9. The method for manufacturing a semiconductor device according to claim 8, wherein the amorphous carbon film is processed until the substrate to be processed is exposed using an intermediate mask layer formed on the amorphous carbon film as a mask, the remaining intermediate mask layer is sputtered to form the protective film.

10. The method for manufacturing a semiconductor device according to claim 9, wherein the intermediate mask layer comprises at least silicon dioxide and the protective film comprises the silicon dioxide.

11. The method for manufacturing a semiconductor device according to claim 10, wherein sputtering the intermediate mask layer is performed using a gas system containing no oxygen.

12. The method for manufacturing a semiconductor device according to claim 10, wherein the substrate to be processed comprises a silicon nitride film as a layer to be processed.

13. The method for manufacturing a semiconductor device according to claim 1, wherein processing the amorphous carbon film is performed by etching using a gas system containing oxygen.

14. The method for manufacturing a semiconductor device according to claim 1, wherein processing the amorphous carbon film is performed by etching using a mixed gas of hydrogen and nitrogen.

15. A method for manufacturing a semiconductor device that includes processing a substrate to be processed by using an amorphous carbon hard mask, comprising:
processing an amorphous carbon film formed on the substrate to be processed to provide a hard mask, and
forming a protective film on a sidewall of the amorphous carbon film exposed during or after processing the amorphous carbon film under the atmosphere containing no oxygen.

16. The method for manufacturing a semiconductor device according to claim 15, wherein processing an amorphous carbon film is performed by using an intermediate mask layer formed on the amorphous carbon film as a mask and the protective film on a sidewall of the amorphous carbon film is formed by sputtering the remaining intermediate mask layer using a gas system containing no oxygen.

17. The method for manufacturing a semiconductor device according to claim 16, wherein the intermediate mask layer comprises at least silicon dioxide and the protective film comprises the silicon dioxide.

18. The method for manufacturing a semiconductor device according to claim 15, wherein processing an amorphous carbon film to provide a hard mask comprises:
forming the amorphous carbon film on the substrate to be processed, and forming an intermediate mask layer on the amorphous carbon film;
processing the intermediate mask layer into a mask shape for a predetermined pattern;
etching a part of the amorphous carbon film using the processed intermediate mask layer as a mask to expose a sidewall of the amorphous carbon film;
sputtering the intermediate mask layer using a gas system containing no oxygen to form a protective film on the sidewall of the amorphous carbon film; and
further etching the amorphous carbon film using the remaining intermediate mask layer and the protective film on the sidewall of the amorphous carbon film as a mask.

19. The method for manufacturing a semiconductor device according to claim 18, wherein the intermediate mask layer comprises at least silicon dioxide and the protective film comprises the silicon dioxide.

20. The method for manufacturing a semiconductor device according to claim 15, wherein after the amorphous carbon film has been processed until the substrate to be processed is exposed, the protective film is formed on the sidewall of the processed amorphous carbon film.

21. The method for manufacturing a semiconductor device according to claim 20, wherein the amorphous carbon film is processed until the substrate to be processed is exposed using an intermediate mask layer formed on the amorphous carbon film as a mask, the remaining intermediate mask layer is sputtered to form the protective film using a gas system containing no oxygen.

22. The method for manufacturing a semiconductor device according to claim 21, wherein the intermediate mask layer comprises at least silicon dioxide and the protective film comprises the silicon dioxide.

23. The method for manufacturing a semiconductor device according to claim 15, wherein processing the amorphous carbon film is performed by etching using a mixed gas of hydrogen and nitrogen.
